(19) United States
(12) Patent Application Publication
(10) Pub. No.: US 2008/0082888 A1
(43) Pub. Date: Apr. 3, 2008

(54) Measurement and calibration method for embedded diagnostic systems

(76) Inventors: David W. Murray, Windsor, CA (US); Kim Chung Thi Thanh, Rohnert Park, CA (US); Bruce A. Erickson, Santa Rosa, CA (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/515,056

(22) Filed: Sep. 1, 2006

(51) Int. Cl. G01R 31/28; G06F 11/00

(52) U.S. Cl. 714/742

(57) ABSTRACT

An apparatus for performing an embedded diagnostic test on a piece of equipment, the equipment including a plurality of components and defining various pathways through respective subsets of the components, comprises an input stimulus generator for generating stimulus signals, coupled to provide the stimulus signals as input to the functionality of the equipment, respective ones of the stimulus signals exercising respective ones of the subsets of components; wherein the stimulus signals include a subset of core stimulus signals, such that a given one of the pathways includes a plurality of segments, different ones of the core stimulus signals exercising different ones of the segments of the given one of the pathways.

### BACKGROUND OF THE INVENTION

The present invention relates to diagnostic testing for electronic equipment.

Conventional diagnostic testing arrangements have involved coupling a test system, such as a production line Unix workstation, to an instrument or piece of equipment to be tested. Troubleshooting software applications, in the form of BASIC or C language programs or shell scripts, etc., reside within the test system.

When such troubleshooting software applications are executed, the test system, and the instrument to be tested, communicate through a communication interface. For instance, many such troubleshooting applications use an IEEE 488 General Purpose Interface Bus (GPIB) connection between the UNIX workstation and the instrument.

It would be advantageous to employ standard network communications for such diagnostic testing, obviating the need for a diagnostic-specific interface such as the GPIB and allowing for remote testing. It would also be advantageous to execute diagnostic testing on-board the equipment to be tested.

### SUMMARY OF THE INVENTION

An apparatus for performing an embedded diagnostic test on a piece of equipment, the equipment including a plurality of components and defining various pathways through respective subsets of the components, comprises an input stimulus generator for generating stimulus signals, coupled to provide the stimulus signals as input to the functionality of the equipment, respective ones of the stimulus signals exercising respective ones of the subsets of components; wherein the stimulus signals include a subset of core stimulus signals, such that a given one of the pathways includes a plurality of segments, different ones of the core stimulus signals exercising different ones of the segments of the given one of the pathways.

Further features and advantages of the present invention, as well as the structure and operation of preferred embodiments of the present invention, are described in detail below with reference to the accompanying exemplary drawings.

### BRIEF DESCRIPTION OF THE DRAWINGS

FIG. 1 is a block diagram showing a system for performing diagnostic testing of a piece of equipment, which is an environment within which an embodiment of the invention is practiced.

FIG. 2 is a flowchart showing an embodiment of the invention.

### DETAILED DESCRIPTION

A system embodying the invention includes self-contained embedded diagnostics for a piece of electronic equipment. Among other fields, such a system may be employed in a measurement apparatus for radiofrequency (hereinafter “RF”) systems.

In such systems, it is desirable to be able to self-diagnose problems which can be solved by replacing sub-assemblies, cables, etc., without requiring the use of external test and measurement equipment. A diagnostic performed by a system embodying the invention can identify an indicted component, a failing component, or the component most likely to fail or to have failed. Also, the particular nature of the fault or failure can be identified. When such a problem is diagnosed, service personnel not necessarily requiring great expertise or training, can replace the problem component.

Where a separate, or remotely located, test system is employed, an operator has knowledge and control over test menus, test system upgrades, secondary testing chosen based on the results of primary testing, etc. However, where the equipment includes an embedded test system having embedded diagnostic capability, the operator may not have control as comprehensive as that just described.

Therefore, there is a need to maximize, or optimize, the amount of confidence an operator can have, in the test stimulus signals employed by the embedded diagnostic test system.

Test systems operate by providing, to the equipment to be tested, a stimulus, in the form of a set of signals which, as a stimulus, will cause the equipment to produce an expected set of responses if it is properly implemented and functioning. The expected responses can include, among other things, a calibration or alignment of the equipment, so as to prepare it for its intended use.

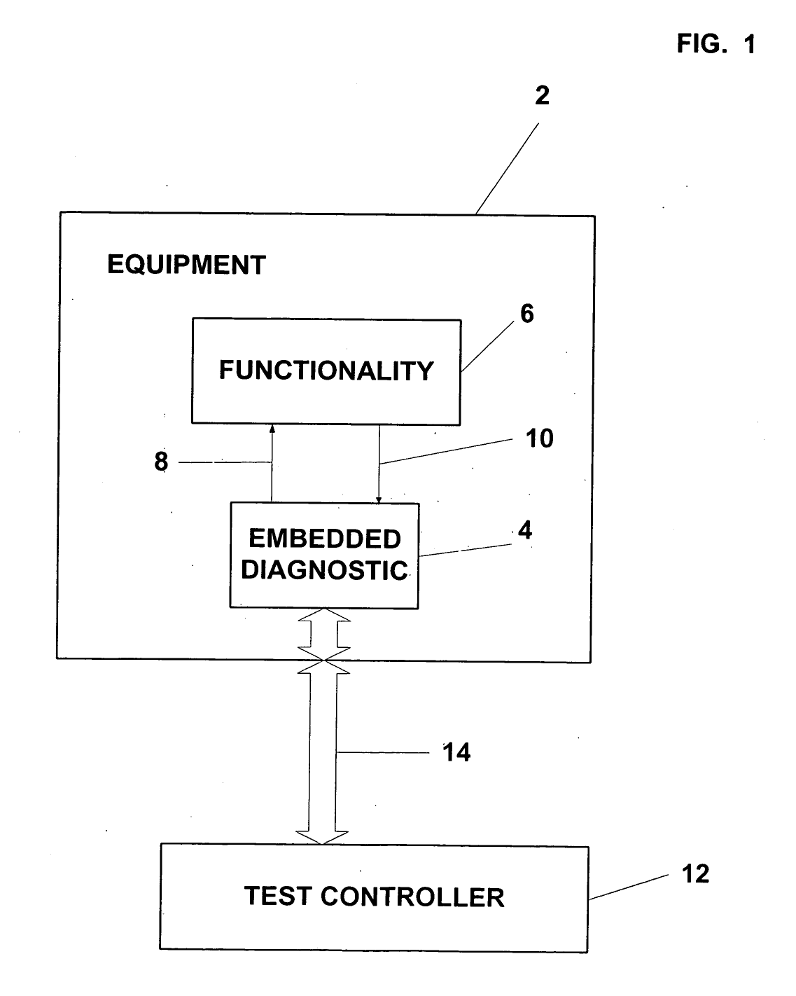

For instance, FIG. 1 is a schematic block diagram of a system in which a piece of equipment 2, which is to be tested, includes an embedded diagnostic apparatus 4. The equipment 2 has a general functionality 6, whose nature is not essential to the present invention but is characteristic of the type of equipment 2. The diagnostic apparatus 4 provides input stimulus signals to the functionality 6 through an input 8, and receives response signals through an output 10. Optionally, the diagnostic 4 can be controlled by an external test controller 12, through a communication link 14.

In the discussion which follows, the term “indicted” will be used to describe a component, sub-assembly, etc., of the equipment 2, for which a problem has been diagnosed. Also, the terms “component” and “communication component” will be used interchangeably, to refer broadly and without limitation to any sub-assembly, cable, interface, component, etc., within a communications system, for which a fault may occur. The term “fault” will refer to any problem that is, or can be, isolated within a particular component of the communication system. Finally, the term “device under test” or “DUT” will be used to refer to the equipment 2 to be tested.

The concepts of (ii) troubleshooting equipment to identify problems, and (ii) calibrating the equipment for optimum or threshold satisfactory and uniform performance, can overlap in the context of diagnostic testing, particularly testing using diagnostic tools embedded within the equipment. In particular, embedded diagnostic apparatus embodying the present invention may perform both the troubleshooting and calibration functions.

A piece of equipment, such as a spectrum analyzer, RF test and measurement equipment, etc., performs against a set of performance specifications (also called “test line limits” or “test limits”), and is calibrated so as to conform to those specifications, within a given tolerance. Where the calibration meets such tolerance, it is said that the equipment is “aligned.” The equipment is calibrated, i.e., aligned, at the factory prior to customer shipment. It is also possible to check alignment as the equipment is being used.

Based on the results of the analysis, it is possible to calibrate the equipment. As an instrument proceeds through our final test process gaining more calibration, the expectation on its performance also increases.

In one embodiment of the diagnostic testing method of the invention, testing becomes more specific as the device under test moves through tests, or iterations of the tests. That is, the test line limits are changed, to become more stringent, in such successive tests or iterations. As the calibration improves with successive, more stringent iterations, the performance of the equipment conforms more and more closely with a predetermined optimum performance. Pieces of equipment that are iteratively calibrated and conform closely with the predetermined optimum performance become increasingly interchangeable and identical in performance. As a result, different systems, which employ the same make and model of equipment so calibrated, function in an increasingly consistent manner.

For instance, in an embedded diagnostic system and method for RF measurement equipment, certain tests such as flatness (i.e., amplitude vs. frequency correction data) also become naturally more accurate as the instrument receives more calibration. A given system test is used in a series of iterations, with a successively different test limits. The test limit changes depend on which ordinally-numbered iteration (i.e., the first iteration, the fourth iteration, etc.) in the series of iterations the instrument is being tested.

Test stimulus signals are used, for instance, for firmware alignments which run automatically when the device under test needs them. If the stimulus signals designed or programmed into an embedded test system fail to meet, or due to changed conditions cease to meet, the expected performance, then confidence in the adequacy of the internal alignment is necessarily low. When such internal alignments are made with bad stimulus signals, the device under test can begin to behave inappropriately. The problem of this inappropriate behavior may be characterized as a form of aliasing.

As an aside, here is a general definition of “aliasing.” In statistics, signal processing, and related disciplines, the term “aliasing” refers to an effect that causes different continuous signals to become indistinguishable (or “aliases” of one another) when sampled. When this happens, the original signal cannot be uniquely reconstructed from the sampled signal. Aliasing can take place either in time (“temporal aliasing”), or in space (“spatial aliasing”).

For the purpose of the present invention, “aliasing” refers to a situation in which the cause of failure cannot be reconstructed from the effect. That is, a diagnosis of the particular nature of the failure (which component is faulty, and what is the problem with it) cannot be ascertained from the list of pass & fails produced by the diagnostic test. Where this is the case, we cannot diagnose the failure accurately, because the test results or syndrome have some inconsistent results.

Aliasing, in this sense, alludes to the fact that, since some test results are dependant on the results of prior tests, if a prior test fails or has issues, then the dependant test(s) can give very inconsistent results. The problem with aliasing is that the particular aliasing effect on any dependant test(s) will vary with the magnitude or degree of the failure in the prior test on which they are dependant. If there are multiple dependencies, then the complexity quickly begins to become unmanageable.

Here is an example of such aliasing. In a radiofrequency (RF) spectrum analyzer (hereinafter the “equipment” or the “instrument”), diagnostic tests may be performed in order to calibrate the instrument. For instance, a piece of RF measurement equipment includes multiple RF measurement pathways, which require system gain alignment. The different measurement pathways, may include, for instance, attenuation stages having various attenuation values, expressed in terms of the number of decibels (dB) of attenuation they provide. Calibration is performed by an iterated set of alignments, in which each successive iteration uses more stringent tolerances. See, for instance, co-pending United States Patent Applications (Agilent PDNO 10060474 and 10060477, USPTO serial numbers to be inserted).

In an automatic alignment test, we use test results generated by such alignments. One of the calibrations is for an Electronic Attenuator (EA). An EA reference state is set up and measured. All other EA states are measured relative to this state. Let us suppose that the reference state is 10 dB, so that the correction for the 12 dB attenuator should be approximately 12-10=2 dB relative to the 10 dB reference.

Now suppose that our stimulus signal is not working. We could measure the 10 dB attenuator amplitude as being the instrument noise floor. The relative corrections have a good chance of passing, despite the problem with the stimulus signal, since the spectrum analyzer noise floor (NF) changes with attenuation (10 dB change in Attenuator setting gives 10 dB change in NF for the most part).

Moreover, for small relative attenuator changes of a few dB's, say 8 dB (−2 dB relative) and 12 dB (+2 dB relative) settings, it is possible, due to the random nature of noise, that the relative difference in calibration at these settings is measured as being larger or smaller than it should be, such that these relative steps will fail specification limits. If this were to happen, then the 8 dB and 12 dB attenuation stages would fail, and the other stages would pass.

If no other measurements were made to detect the true cause, then the diagnostic algorithm would wrongly indict the Electronic Attenuator, when in fact the stimulus signal was bad. The reason it did this was that, for each EA attenuation step being measured, the only component change was in the Electronic Attenuator. Some stages passed and some failed. All other things being equal, the diagnostic algorithm will determine, incorrectly, that the 8 dB and 12 dB attenuators are bad.

To get around this problem, in an embodiment of the invention we measure the actual amplitude of the stimulus signal in the reference condition. If it fails, then we set all dependant tests to “skip” (i.e., to disregard the test results; see, for instance, co-pending U.S. Patent Application (Agilent PDNO 10060477, USPTO serial number TBD), but have the reference item fail to maintain the possible indictment of components used in this pathway. For instance, the system gain alignment of the RF spectrum analyzer discussed above may be affected by the sort of aliasing just described:

The system gain alignments are always trying to align gains using stimulus signals which were previously calibrated to a target value established when the DUT was tested in electrical inspection (EI). At times this causes the system to measure the correct amplitude, even when the stimulus signals levels or path gains have physically strayed from their expected values. Accordingly, the operator cannot have confidence that the diagnostic test is giving satisfactory results.

In an embodiment of the invention, CW (Continuous Wave) calibration signals are aligned (set) to a specific target value. The analyzer will use these target values to re-align the path gains at explicit time intervals and over temperature change, to assist the analyzer in functioning as an accurate measurement system.

In order for the analyzer to align appropriate gains for the path being measured, it needs to know what the correct amplitude (target value) should be. In an analyzer embodying the invention, all the system gains in particular measurement paths, or the corrections at any measurement frequency, are made relative to a few internal calibration signals. Since everything is measured relative to these calibration signals and then stored in the instrument as alignment or calibration data, then it follows that, as far as the analyzer is concerned, it always measures the correct signal level (“relative” to actual calibration signal amplitude) at any frequency (within the repeatability of the instrument and fundamental measurement accuracy of the calibration). In actuality the analyzer will not read the correct “absolute” amplitude accuracy until the internal calibration signals themselves have been measured and set against a piece of external equipment (normally a power meter).

So, when we align analyzer path gains, we only do this to a target amplitude value, which may or may not be “absolutely” correct. The instrument does not know the difference. The instrument is dependant on our test process making the necessary calibration to an external measurement system to make its internal amplitude “absolutely” correct.

Path Gain=Path Measured Value−Target Value

Path Gain=−27−−25

Path Gain=−2

The path correction required to measure −25 (Target Value) would be the negative of the Path Gain, i.e., a value of +2. Now that we have ascertained and stored a path correction value based on the Path Gain, we then can run a test, and meaningfully interpret the measured test results (that is, the Path measured Value), as follows:

$$\begin{matrix}Aligned Measured Value = path correction + Path Measured Value \\ = 2 + \text{-} 27 \\ = \text{-} 25 ( same as target value )\end{matrix}$$

Notice that, since the alignments happen over time and temperature, the same Path Aligned value may be used for many subsequent measurements, such that we don't always get exactly to the target for any new measured value. This goes to the issue of measurement repeatability. Consider, for instance, a subsequent test, as follows:

$$\begin{matrix}Aligned Measured Value = path correction + New Path Measured Value \\ = 2 + \text{-} 27.05 \\ = \text{-} 25.05 \\ ( close to , but not exactly at , Target Value )\end{matrix}$$

With reference to the above examples, here are a few definitions:

Correct Amplitude is a measured amplitude that is very close to the target amplitude value (so therefore “correct” or “corrected”).

Gain Alignment (or just alignment) refers to the measurement process which calculates the Path Gain (see explanation above).

Since the analyzer will always align the appropriate path to a target value, there is an assumption that the instrument is able to supply a signal which nominally works. If the calibration signal, for instance, stops working, then the internal alignment will still try to set the path to the target value. If the measured value is noise, then the aligned path gain will have to be very large, perhaps even a gain larger than the instrument is physically able to provide. This would cause “aliasing” of any measurements that are dependant on the correct operation of this path and calibration signal.

In order to avoid the aliasing effects that can happen when bad hardware is present, in an embodiment of the invention we endeavor to make measurements with known good signals. This assurance process begins with the internal alignments: we measure the amplitude of the signal used for the alignment, before running the alignments.

However, since the instrument is always trying to align to a target value, it would be possible, in some situations, that it can set a path gain that will provide the target value, but still not be a valid signal, for example, in the extreme case where the signal does not exist and we are measuring the instrument noise floor.

In an embodiment of the invention, this possibility is mitigated by measuring the signal-to-noise ratio of the calibration signal. We measure the amplitude of the aligned path without a calibration signal, and then we measure the amplitude of the aligned path with the calibration signal. The amplitude difference is the signal-to-noise ratio. In one embodiment, we normally scale the value to a predetermined value, such as a 1 Hz measurement bandwidth, for consistency. This can mitigate some other type of aliasing problems that are due to the DUT not being physically configured to the settings that the instrument firmware thinks have been set.

To address this concern, in an embodiment of the invention, certain specific stimulus signals, designated “core signals”, are employed, in a manner to be described. In the exemplary RF system, three such core stimulus signals are as follows:
50 MHz CW
322.5 MHz Comb
4.8 GHz CW

There are also two auxiliary signals, as follows.
DC Source
Noise Source.

When stimulus signal aliasing occurs, some confidence in measurements can be restored by measuring signal levels of the core stimulus signals, and comparing the results with the expected values. As per the discussion of pathways (above), the calibration (or stimulus) signals have pathways routed through specific hardware. For example, the 50 MHz and the 4800 MHz core stimulus signals are routed to the input of the instrument.

The 50 MHz ECal and the 322 MHz signals are routed to the first mixer, which in the exemplary RF spectrum analyzer is three subassemblies in from the input connector. The 322 MHz signal can also be routed to the final mixer stage.

The combination of all these signal paths allows us to split up the full measurement path into segments, making embedded diagnosis much easier.

The 2 auxiliary signals, Noise Source and DC Source, further enhance the ability to split up the measurement pathways, as follows:

| | | | |
|---|---|---|---|
| Signal | input | Measurement Path | ADC |

| | | |
|---|---|---|
| 50 MHz | input | full low band path |
| 4800 MHz | input | full high band path |
| 50 MHz | ECal | partial low band path |
| 322 MHz | ECal | partial low band path |
| 322 MHz | AIF | common path |
| DC Signal | input | low band path |
| Noise Source | | partial high band path |

For the foregoing discussion, here are some definitions of terms:

### Terms of Reference

### ADC—Analog to Digital Converter

### High band—Path for frequencies greater than 3.6 GHz

### Low band—Path for frequencies less than 3.6 GHz

### AIF—Analog Intermediate Frequency

### ECal—Electronic Calibration, for instance Internal Electronic Calibration

When a stimulus signal power level has changed from its calibrated level, the device under test still believes that this signal is still set to this targeted power level. Since these stimulus signals traverse the RF measurement chain, then the signal level could be changed by a bad component, or by the hardware control not being cognoscente of actual DUT settings due to hardware failure. This may cause aliasing in the internal alignments.

Since no external power measurements can be made, the signal-to-noise ratio of each of the stimulus signals is measured at the final intermediate frequency (IF), to make sure these levels fall within the allowable range of correctly performing signals. Because the three measurement paths are unique, there is only a low probability that all three will be affected the same way by any hardware fault.

The RF spectrum analyzer system is tested when it is first assembled into a final product, but before it has received much electrical inspection (EI) testing. This has been a problem in the past, because the high frequency path above 3.6 GHz has a preselecting filter implemented in YTF (YIG (Yttrium-Iron-Garnet) Tuned Filter) technology. This conventionally has had to be calibrated with an external source, in order to develop an algorithmic tuning curve which will center the prefilter on the equipment under test for the covered range of tuned frequencies. In an embodiment of the invention using the noise source, the equipment's YTF prefilter can be calibrated with no external equipment.

The DC Source can be used to measure the impedance of specific paths configured in hardware. This is useful for detecting failures near the front end of the instrument.

At the front end of the system it is very difficult to design broadband detectors which don't adversely affect instrument performance. In an embodiment of the invention, introducing a DC signal into the front-end of the path removes any RF performance degradations, but at the same time allows impedance measurements of the selected hardware path to be made.

Although the present invention has been described in detail with reference to particular embodiments, persons possessing ordinary skill in the art to which this invention pertains will appreciate that various modifications and enhancements may be made without departing from the spirit and scope of the claims that follow.

What is claimed is:

1. An apparatus for performing an embedded diagnostic test on a piece of equipment, the equipment including a plurality of components and defining various pathways through respective subsets of the components, the apparatus comprising:
an input stimulus generator for generating stimulus signals, coupled to provide the stimulus signals as input to the functionality of the equipment, respective ones of the stimulus signals exercising respective ones of the subsets of components;
wherein the stimulus signals include a subset of core stimulus signals, such that a given one of the pathways includes a plurality of segments, different ones of the core stimulus signals exercising different ones of the segments of the given one of the pathways.

2. An apparatus as recited in claim 1, wherein:
the equipment includes a radiofrequency (RF) system; and
the subset of core stimulus signals includes a plurality core stimulus signals at respective predetermined frequencies.
